(19) United States
(12) Patent Application Publication
(10) Pub. No.: US 2025/0254869 A1
(43) Pub. Date: Aug. 7, 2025

(54) VERTICAL NONVOLATILE MEMORY DEVICE, ELECTRONIC APPARATUS INCLUDING THE SAME, AND METHOD OF MANUFACTURING MEMORY DEVICE

(71) Applicant: SAMSUNG ELECTRONICS CO., LTD., Suwon-si (KR)

(72) Inventors: Minhyun LEE, Suwon-si (KR); Jinjoo PARK, Suwon-si (KR); Seonghun JANG, Suwon-si (KR); Seokhoon CHOI, Suwon-si (KR)

(73) Assignee: SAMSUNG ELECTRONICS CO., LTD., Suwon-si (KR)

(21) Appl. No.: 18/934,922

(22) Filed: Nov. 1, 2024

(30) Foreign Application Priority Data
Feb. 6, 2024 (KR) 10-2024-0018422

(51) Int. Cl. H10B 41/30; H01L 29/788; H10B 41/40

(52) U.S. Cl. CPC H10B 41/30; H10B 41/40; H10D 30/683

(57) ABSTRACT

A nonvolatile memory device includes a plurality of cell strings each including a channel layer extending in a first direction, at least one charge tunneling layer adjacent to the channel layer in a second direction intersecting the first direction, a plurality of charge storage layers adjacent to the at least one charge tunneling layer in the second direction, the plurality of charge storage layers spaced apart in the first direction, a plurality of charge blocking layers adjacent to respective charge storage layers of the plurality of charge storage layers in the second direction, a plurality of gate electrodes adjacent to respective charge blocking layers of the plurality of charge blocking layers in the second direction, and a plurality of separation layers configured to isolate the plurality of charge storage layers, the plurality of charge blocking layers, and the plurality of gate electrodes in the first direction.

### CROSS-REFERENCE TO RELATED APPLICATION

This application is based on and claims priority under 35 U.S.C. § 119 to Korean Patent Application No. 10-2024-0018422, filed on Feb. 6, 2024, in the Korean Intellectual Property Office, the disclosure of which is incorporated by reference herein in its entirety.

### BACKGROUND

### 1. Field

The disclosure relates to a vertical nonvolatile memory device, an electronic apparatus including the same, and a method of manufacturing a memory device.

### 2. Description of Related Art

Nonvolatile memory devices may include a plurality of memory cells that retain information even when power supply is interrupted and may use stored information again when power is supplied. Such nonvolatile memory devices may be widely applied to mobile phones, digital cameras, personal digital assistants (PDAs), portable computer apparatuses, etc.

Recently, as high integration and low power are required, vertical NAND (VNAND) flash memory devices have been developed. In VNAND flash memory devices, charge transfer between memory cells may occur due to an increase in the number of stacked layers and a decrease in the height of memory cells, and this charge transfer may worsen charge retention characteristics of the memory cells.

### SUMMARY

Provided is vertical nonvolatile memory device that may be capable of improving charge retention characteristics of memory cells.

Further provided is a vertical nonvolatile memory device that may be capable of reducing process costs.

Additional aspects will be set forth in part in the description which follows and, in part, will be apparent from the description, or may be learned by practice of the presented embodiments of the disclosure.

According to an aspect of the disclosure, a nonvolatile memory device may include a plurality of cell strings, where each of the plurality of cell strings may include a channel layer extending in a first direction, at least one charge tunneling layer adjacent to the channel layer in a second direction intersecting the first direction, a plurality of charge storage layers adjacent to the at least one charge tunneling layer in the second direction, the plurality of charge storage layers spaced apart in the first direction, a plurality of charge blocking layers adjacent to respective charge storage layers of the plurality of charge storage layers in the second direction, a plurality of gate electrodes adjacent to respective charge blocking layers of the plurality of charge blocking layers in the second direction, and a plurality of separation layers configured to isolate the plurality of charge storage layers, the plurality of charge blocking layers, and the plurality of gate electrodes in the first direction, where the plurality of charge storage layers include a semiconductor material doped with a dopant at a doping concentration of 10¹⁸ atm/cm³ or higher.

The semiconductor material may include silicon (Si).

The semiconductor material may include polysilicon.

The dopant may include an n-type dopant.

The n-type dopant may include arsenic (As) or phosphorus (P).

The dopant may include boron (B), carbon (C), or germanium (Ge).

The at least one charge tunneling layer may extend in the first direction and may be configured to be shared by the plurality of charge storage layers.

The at least one charge tunneling layer may include a plurality of charge tunneling layer that are respectively separated by the plurality of separation layers and respectively correspond to the plurality of charge storage layers.

The plurality of charge tunneling layers may protrude from an outer peripheral surface of the channel layer to an inner side of the channel layer.

The at least one charge tunneling layer may include silicon oxide.

A compressive stress of the plurality of charge blocking layers may be −50 MPa to −300 MPa.

According to an aspect of the disclosure, a method of manufacturing a memory device may include alternately stacking a plurality of separation layers and a plurality of semiconductor material layers on a substrate, forming a through hole in the plurality of separation layers and the plurality of semiconductor material layers, forming, in each semiconductor material layer of the plurality of semiconductor material layers, a first area adjacent to the through hole and a second area adjacent to the first area, by injecting a dopant into the plurality of semiconductor material layers by the through hole, where the first area is doped with the dopant, and the second area is not doped, forming at least one charge tunneling layer on an inner wall of the through hole, forming a channel layer on an inner wall of the at least one charge tunneling layer, forming a partition groove partitioning a plurality of cell strings, and forming a charge storage layer by etching and removing the second area of each semiconductor material layer of the plurality of semiconductor material layers through the partition groove, such that the first area of each semiconductor material layer of the plurality of semiconductor material layers remains.

The plurality of charge storage layers may include a semiconductor material, and the semiconductor material may include silicon (Si).

A doping concentration of the first area may be 10¹⁸ atm/cm³ or higher.

The at least one charge tunneling layer may include silicon oxide and conformally covers the inner wall of the through hole.

The forming of the at least one charge tunneling layer may include forming a plurality of charge tunneling layers at positions respectively corresponding to the first area of each semiconductor material layer of the plurality of semiconductor material layers.

The forming of the plurality of charge tunneling layers may include forming silicon oxide by partially oxidizing silicon in the first area, and the silicon oxide may protrude inward from the inner wall of the through hole.

The method may include forming a charge blocking layer through the partition groove and forming a gate electrode adjacent to the charge blocking layer.

The semiconductor material layer may include silicon, and the forming the charge blocking layer may include forming silicon oxide by partially oxidizing silicon in each first area of each semiconductor material layer of the plurality of semiconductor material layers.

According to an aspect of the disclosure, an electronic apparatus may include a memory, and a memory controller configured to control the memory to read data from the memory and/or write data into the memory, where the memory may include a nonvolatile memory device, the nonvolatile memory device may include a plurality of cell strings, and each of the plurality of cell strings may include a channel layer extending in a first direction, at least one charge tunneling layer adjacent to the channel layer in a second direction intersecting the first direction, a plurality of charge storage layers adjacent to the at least one charge tunneling layer in the second direction, the plurality of charge storage layers spaced apart in the first direction, a plurality of charge blocking layers adjacent to respective charge storage layers of the plurality of charge storage layers in the second direction, a plurality of gate electrodes adjacent to respective charge blocking layers of the plurality of charge blocking layers in the second direction, and a plurality of separation layers configured to isolate the plurality of charge storage layers, the plurality of charge blocking layers, and the plurality of gate electrodes in the first direction.

The plurality of charge storage layers may include a semiconductor material doped with a dopant at a doping concentration of 10¹⁸ atm/cm³ or higher.

Each cell string of the plurality of cell strings may include a plurality of diffusion prevention layers respectively between the plurality of gate electrodes and the plurality of charge blocking layers.

The plurality of diffusion prevention layers may be respectively between the plurality of gate electrodes and the plurality of separation layers.

The at least one charge tunneling layer may include a plurality of charge tunneling layers, and each charge tunneling layer of the plurality of charge tunneling layers may protrude from an outer peripheral surface of the channel layer.

Each charge tunneling layer of the plurality of charge tunneling layers may include a portion that extends into the channel layer.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a perspective view of a vertical nonvolatile memory device according to one or more embodiments;

FIG. 2 is a cross-sectional view taken along a line A-A′ of FIG. 1 according to one or more embodiments;

FIG. 3 is an enlarged view of area D1 of FIG. 2 according to one or more embodiments;

FIG. 4 is a circuit diagram of a vertical nonvolatile memory device according to one or more embodiments;

FIG. 5 is a cross-sectional view of a vertical nonvolatile memory device according to one or more embodiments;

FIG. 6 is an enlarged view of area D2 of FIG. 5 according to one or more embodiments;

FIGS. 7A to 71 are diagrams of a method of manufacturing the vertical nonvolatile memory device according to one or more embodiments;

FIG. 8 is a graph illustrating a change in silicon etch rate according to the concentration of a dopant in an etching process using tetramethylammonium hydroxide (TMAH), according to one or more embodiments;

FIG. 9 is a graph illustrating a change in silicon etch rate according to the concentration of a dopant in an etching process using an ethylenediamine-pyrocatechol-water solution (EDP) aqueous solution, according to one or more embodiments;

FIGS. 10A to 10F are diagrams of a method of manufacturing the vertical nonvolatile memory device according to one or more embodiments;

FIG. 11 is a block diagram of a display driver integrated circuit (DDI) and a display apparatus including a DDI, according to one or more embodiments;

FIG. 12 is a diagram of an electronic apparatus according to one or more embodiments;

FIG. 13 is a diagram of an electronic apparatus according to one or more embodiments;

FIG. 14 is a diagram of a device architecture that may be applied to an electronic apparatus, according to one or more embodiments; and

FIG. 15 is a diagram of a device architecture that may be applied to an electronic apparatus, according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a vertical nonvolatile memory device and an electronic apparatus including the same, according to various embodiments, will be described in detail with reference to the accompanying drawings. The embodiments described below are merely exemplary, and various modifications are possible from these embodiments. In the following drawings, the same reference numerals refer to the same components, and the size of each component in the drawings may be exaggerated for clarity and convenience of description.

In the following description, when a component is referred to as being “above” or “on” another component, it may be directly on an upper, lower, left, or right side of the other component while making contact with the other component or may be above an upper, lower, left, or right side of the other component without making contact with the other component.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

In addition, terms such as “unit” and “module” described in the specification may indicate a unit that processes at least one function or operation, and this may be implemented as hardware or software, or may be implemented as a combination of hardware and software.

The singular forms “a,” “an,” and “the” as used herein are intended to include the plural forms as well unless the context clearly indicates otherwise.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

The size or thickness of each element in the drawings may be exaggerated for clarity of description. In addition, when it is described that a certain material layer is present on a substrate or another layer, the material layer may be present in direct contact with the substrate or the other layer, or a third layer may be present therebetween. Furthermore, because materials forming each layer in the following examples are illustrative, other materials may be used.

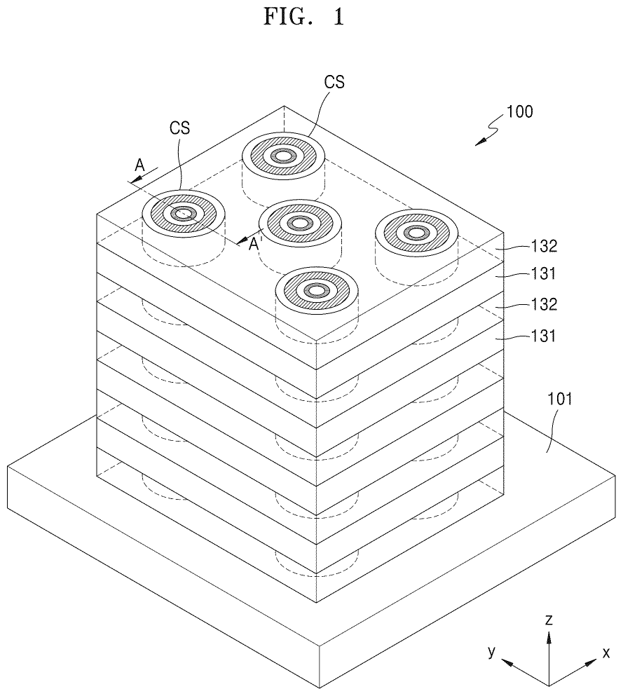

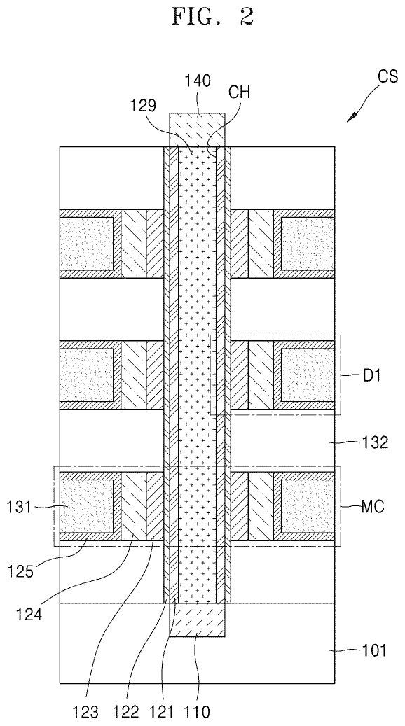

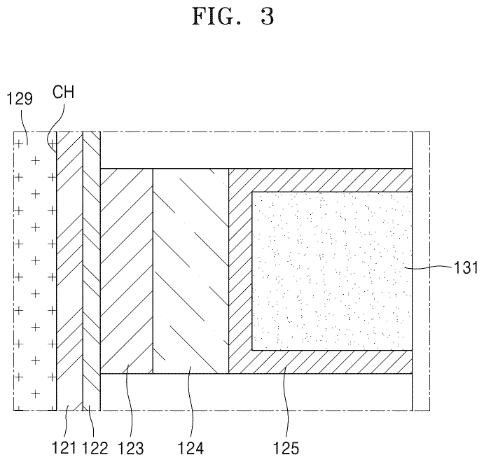

FIG. 1 is a perspective view of a vertical nonvolatile memory device 100 according to one or more embodiments. FIG. 2 is a cross-sectional view of the vertical nonvolatile memory device 100 taken along a line A-A′ of FIG. 1, according to one or more embodiments. FIG. 3 is an enlarged view of area D1 of FIG. 2, according to one or more embodiments.

Referring to FIG. 1, the vertical nonvolatile memory device 100 may include a plurality of cell strings CS arranged on a substrate 101. The plurality of cell strings CS may extend in a direction (i.e., a Z direction in FIG. 1) perpendicular to the substrate 101. The plurality of cell strings CS may be arranged in various shapes on the substrate 101. A gate electrode 131 and a separation layer 132 may be alternately stacked on the substrate 101. Each of the plurality of cell strings CS may include a channel hole CH passing through a stack of the gate electrode 131 and the separation layer 132 in the direction (e.g., Z direction) perpendicular to the substrate 101. The channel hole CH may be formed to have, for example, a circular cross-section. However, the cross-sectional shape of the channel hole CH is not limited thereto. An area of each cell string CS excluding the gate electrode 131 and the separation layer 132 may have a structure in which a plurality of material layers having a cylindrical shell shape are stacked outward from the channel hole CH. The plurality of material layers having a cylindrical shell shape may form a memory cell MC. For example, the cell string CS may include a plurality of memory cells MC arranged in the Z direction. Some of the plurality of material layers forming each memory cell MC may be separated in the Z direction from a corresponding material layer of another memory cell MC by the separation layer 132. However, the structure of the cell string CS is not limited thereto, and the cell string CS may have different shapes and structures.

The substrate 101 may include a single crystal silicon substrate, a compound semiconductor substrate, or a silicon on insulator (SOI) substrate, but is not limited thereto. Also, the substrate 101 may further include, for example, an impurity area caused by doping, an electronic device such as a transistor, and/or a peripheral circuit that selects and controls memory cells that store data.

Referring to FIGS. 2 and 3, the cell string CS may include a plurality of memory cells MC stacked in the direction (e.g., Z direction) perpendicular to the substrate 101. The memory cell MC may be a basic unit cell that writes and erases data.

The cell string CS may include a channel layer 121, a charge tunneling layer 122, a plurality of charge storage layers 123, a plurality of charge blocking layers 124, and a plurality of gate electrodes 131. The channel layer 121, the charge tunneling layer 122, a charge storage layer 123, a charge blocking layer 124, and a gate electrode 131 may form a single memory cell MC. According to one or more embodiments, in the cell string CS, the plurality of memory cells MC may share the channel layer 121 and the charge tunneling layer 122. Other material layers of the plurality of memory cells MC may be separated by a plurality of separation layers 132 in a vertical direction of the channel layer 121 (that is, in the Z direction).

For example, the charge tunneling layer 122 may be provided adjacent to the channel layer 121 in a horizontal direction (e.g., X direction or Y direction) perpendicular to the vertical direction (e.g., Z direction) of the channel layer 121. The charge tunneling layer 122 may surround the outer peripheral surface of the channel layer 121. The charge tunneling layer 122 may extend in the vertical direction. The plurality of charge storage layers 123 may be arranged adjacent to the charge tunneling layer 122 in the horizontal direction and spaced apart in the vertical direction. Each charge storage layer 123 may surround the charge tunneling layer 122. The plurality of charge blocking layers 124 may be respectively arranged on the outer sides of the plurality of charge storage layers 123. Each charge blocking layer 124 may surround a corresponding charge storage layer 123. The plurality of gate electrodes 131 may be respectively arranged on the outer sides of the plurality of charge blocking layers 124. The plurality of separation layers 132 may be configured to separate the plurality of charge storage layers 123, the plurality of charge blocking layers 124, and the plurality of gate electrodes 131 in the vertical direction of the channel layer 121.

A source electrode 110 and a drain electrode 140 may be respectively arranged on a first end and a second end of the channel layer 121 in the vertical direction. The source electrode 110 may also be commonly connected to the plurality of cell strings CS. When a voltage is supplied to the gate electrode 131 of the memory cell MC, a channel may be formed in an inner area of the channel layer 121, which faces the gate electrode 131, and charges flowing between the source electrode 110 and the drain electrode 140 may pass through the charge tunneling layer 122 and may be captured in the charge storage layer 123 such that information may be stored.

The channel layer 121 may include a semiconductor material. The channel layer 121 may include, for example, silicon (Si), germanium (Ge), SiGe, or a group III-V semiconductor. Also, the channel layer 121 may include, for example, an oxide semiconductor, a nitride semiconductor, a nitride semiconductor, a two-dimensional (2D) semiconductor material, quantum dots (QDs), or an organic semiconductor. In this case, the oxide semiconductor may include, for example, indium gallium zinc oxide (InGaZnO). The 2D semiconductor material may include, for example, transition metal dichalcogenide (TMD) or graphene, and the QDs may include colloidal QDs, nanocrystal structures, or the like. The 2D semiconductor material may refer to a semiconductor material having a 2D crystal structure and may have a monolayer or multilayer structure. The 2D semiconductor material may have excellent electrical characteristics, and even when the thickness thereof is reduced to nanoscale, the characteristics of the 2D semiconductor material do not significantly change and the 2D semiconductor material maintains high mobility. Thus, the 2D semiconductor material may be applied to various devices. Each layer constituting the 2D semiconductor material may have a thickness at an atomic level. The channel layer 121 may include 1 to 10 or more 2D semiconductor material layers.

The 2D semiconductor material may include, for example, at least one of graphene, black phosphorus, and TMD. Graphene may be a material having a hexagonal honeycomb structure in which carbon atoms are two-dimensionally bonded, having high electrical mobility and excellent thermal properties, being chemically stable, and having a large surface area compared to Si. In addition, the black phosphorus may be a material in which black phosphorus atoms are two-dimensionally bonded.

The TMD may be expressed, for example, as MX2, where M represents a transition metal and X represents a chalcogen element. For example, M may include molybdenum (Mo), tungsten (W), niobium (Nb), vanadium (V), tantalum (Ta), titanium (Ti), zirconium (Zr), hafnium (Hf), technetium (Tc), or rhenium (Re), and X may include sulfur(S), selenium (Se), or tellurium (Te). Accordingly, the TMD may include, for example, molybdenum disulfide (MoS₂), molybdenum diselenide (MoSe₂), molybdenum ditelluride (MoTe₂), tungsten disulfide (WS₂), tungsten diselenide (WSe₂), tungsten ditelluride (WTe₂), zirconium disulfide (ZrS₂), zirconium diselenide (ZrSe₂), hafnium disulfide (HfS₂), hafnium diselenide (HfSe₂), niobium diselenide (NbSe₂), or rhenium diselenide (ReSe₂).

Alternatively, the 2D semiconductor material may include copper sulfide (CuS), a compound of copper (Cu), which is a transition metal, and sulfur(S), which is a chalcogen element. In addition, the 2D semiconductor material may include a chalcogenide material including a non-transition metal. The non-transition metal may include, for example, gallium (Ga), indium (In), tin (Sn), Ge, lead (Pb), or the like. In this case, the 2D semiconductor material may include a compound of a non-transition metal, such as Ga, In, Sn, Ge, or Pb, and a chalcogen element, such as S, Se, or Te. For example, the 2D semiconductor material may include tin diselenide (SnSe₂), gallium sulfide (GaS), gallium selenide (GaSe), gallium tellurium (GaTe), germanium selenide (GeSe), indium selenide (In₂Se₃), indium tin disulfide (InSnS₂), or the like. However, the aforementioned materials are only examples and other materials may also be used as 2D semiconductor materials.

The channel layer 121 may further include a dopant. In this case, the dopant may include a p-type dopant or an n-type dopant. The p-type dopant may include, for example, a group III element such as boron (B), aluminum (AI), Ga, or In, and the n-type dopant may include, for example, a group V element such as phosphorus (P), arsenic (As), or antimony (Sb).

In one or more embodiments, the channel layer 121 has a cylindrical shape. Accordingly, the channel hole CH is provided inside the channel layer 121. A pillar 129 may be filled inside the channel hole CH. The pillar 129 may include, for example, silicon oxide (SiO₂) or air, but is not limited thereto.

The charge tunneling layer 122 may be between the channel layer 121 and the charge storage layer 123 and may be a layer in which charge tunneling occurs between the channel layer 121 and the charge storage layer 123. For example, the charge tunneling layer 122 may include SiO₂ or metal oxide, but is not limited thereto. For example, in one or more embodiments, the charge tunneling layer 122 may include SiO₂.

The charge storage layer 123, the charge blocking layer 124, and the gate electrode 131 may be sequentially arranged adjacent to the charge tunneling layer 122 in the horizontal direction in a cross-sectional view. The plurality of gate electrodes 131 may be separated from each other by the separation layer 132.

The charge storage layer 123 may store introduced charges. Charges (e.g., electrons) present in the channel layer 121 may be introduced into the charge storage layer 123 due to the tunneling effect or the like. The charges introduced into the charge storage layer 123 may be fixed to the charge storage layer 123. The charge storage layers 123 may include a semiconductor material doped with a dopant at a doping concentration of 10¹⁸ atm/cm³ or higher. For example, the doping concentration may be 10¹⁹ atm/cm³ or higher. The semiconductor material may include, for example, Si. Si may include, for example, crystalline silicon or polysilicon. In one or more embodiments, the semiconductor material may include polysilicon. The polysilicon may be easily deposited on the separation layer 132 compared to crystalline silicon. The dopant may include, for example, B, carbon (C), Ge, As, or P, but is not limited thereto.

The charge blocking layer 124 may function as a barrier that prevents charges from moving between the charge storage layer 123 and the gate electrode 131. One side of the charge blocking layer 124 may contact the charge storage layer 123, and the other side of the charge blocking layer 124 may contact the gate electrode 131. The charge blocking layer 124 may include SiO₂, metal oxide, or metal nitride, but is not limited thereto. The charge blocking layer 124 may include at least one of aluminum oxide (AlO), magnesium oxide (MgO), aluminum nitride (AlN), and gallium nitride (GaN). In one or more embodiments, the charge blocking layer 124 may include SiO₂. The charge blocking layer 124 may have compressive stress. For example, the compressive stress of the charge blocking layer 124 may be, for example, about −50 MPa to about −300 MPa.

The gate electrode 131 may control a corresponding area of the channel layer 121. A word line may be electrically connected to the gate electrode 131. The gate electrode 131 may include a material having excellent electrical conductivity, such as a metal material, conductive oxide, and metal nitride, Si doped with impurities, or a 2D conductive material. The metal material may include, for example, gold (Au), Ti, titanium nitride (TiN), tantalum nitride (TaN), W, Mo, tungsten nitride (Wn), platinum (Pt), Nb, niobium nitride (NbN), nickel (Ni), or any combinations thereof. The conductive oxide may include, for example, indium tin oxide (ITO), indium zinc oxide (IZO), or the like. However, this is only an example, and the gate electrode 131 may include various other materials.

A diffusion prevention layer 125 may be between the gate electrode 131 and the charge blocking layer 124. The diffusion prevention layer 125 may between the gate electrode 131 and the separation layer 132. The diffusion prevention layer 125 may prevent interfacial reaction and diffusion of atoms between the gate electrode 131 and the charge storage layer 123. The diffusion prevention layer 125 may increase the adhesion between two adjacent material layers, for example, the gate electrode 131 and the charge blocking layer 124, and the gate electrode 131 and the separation layer 132. The diffusion prevention layer 125 may reduce electrical resistance at a contact surface of the two material layers, thereby preventing power loss, temperature increase, and deterioration of operating characteristics of the vertical nonvolatile memory device 100. The diffusion prevention layer 125 may include a material having a higher redox potential than a material of the separation layer 132, for example, SiO₂. The diffusion prevention layer 125 may include at least one of Ti, Zr, V, Al, lanthanum (La), Nb, and Ta, or may include nitride including at least one of the aforementioned materials. The diffusion prevention layer 125 may include, for example, TiN or NbN.

The plurality of separation layers 132 may function as spacers that separate the plurality of charge storage layers 123, the plurality of charge blocking layers 124, and the plurality of gate electrodes 131 in the vertical direction. The separation layer 132 may include, for example, SiO₂, silicon nitride (SiN), or the like, but is not limited thereto. In one or more embodiments, the separation layer 132 comprises SiO₂.

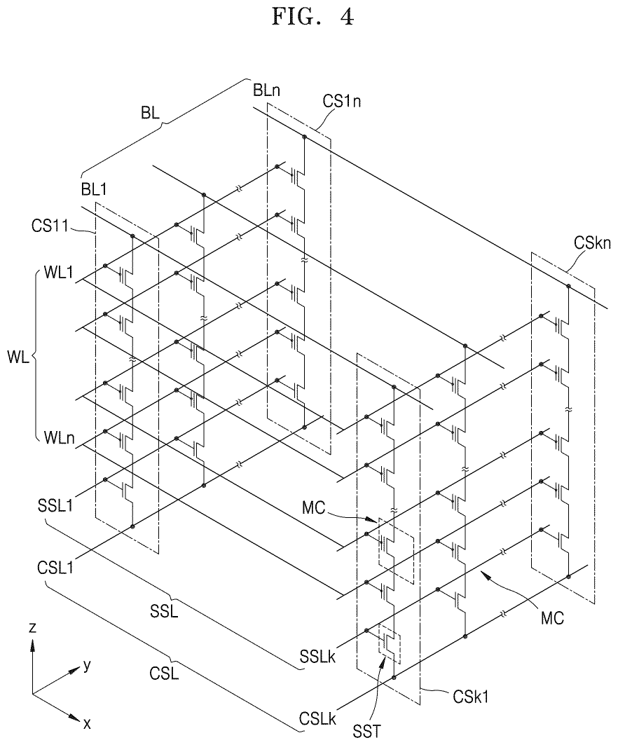

FIG. 4 is a circuit diagram of a vertical nonvolatile memory device according to one or more embodiments. k*n cell strings CS may be provided and arranged in a matrix form, and may be referred to as CSij (1≤i≤k, 1≤j≤n) according to the position of each row and column. Each cell string CSij may be connected to a bit line BL, a string selection line SSL, a word line WL, and a common source line CSL.

Each cell string CSij may include memory cells MC and a string selection transistor SST. The memory cells MC and the string selection transistor SST of each cell string CSij may be stacked in a vertical direction.

Rows of a plurality of cell strings CS may be respectively connected to different string selection lines SSL1 to SSLk. For example, string selection transistors SST of cell strings CS11 to CS1n may be commonly connected to a string selection line SSL1. String selection transistors SST of cell strings CSk1 to CSkn may be commonly connected to a string selection line SSLk.

Columns of the plurality of cell strings CS may be respectively connected to different bit lines BL1 to BLn. For example, memory cells MC and string selection transistors SST of the cell strings CS11 to CSk1 may be commonly connected to a bit line BL1, and memory cells MC and string selection transistors SST of the cell strings CS1n to CSkn may be commonly connected to a bit line BLn.

The rows of the plurality of cell strings CS may be respectively connected to different common source lines CSL1 to CSLk. For example, the string selection transistors SST of the cell strings CS11 to CS1n may be commonly connected to a common source line CSL1, and the string selection transistors SST of the cell strings CSk1 to CSkn may be commonly connected to a common source line CSLk.

The memory cells MC located at the same height from the substrate 101 or the string selection transistors SST may be commonly connected to one word line WL, and the memory cells MC located at different heights may be respectively connected to different word lines WL1 to WLn.

The circuit structure of FIG. 4 shown is an example, but embodiments are not limited thereto. For example, the number of rows of the cell strings CS may increase or decrease. As the number of rows of the cell strings CS changes, the number of string selection lines connected to the rows of the cell strings CS and the number of cell strings CS connected to one bit line BL may also change. As the number of rows of the cell strings CS changes, the number of common source lines connected to the rows of the cell strings CS may also change.

For example, the number of columns of the cell strings CS may be increase or decrease. As the number of columns of the cell strings CS changes, the number of bit lines BL connected to the columns of the cell strings CS and the number of cell strings CS connected to one string selection line may also change.

The height of each cell string CS may also increase or decrease. For example, the number of memory cells MC stacked in each cell string CS may increase or decrease. As the number of memory cells MC stacked in each cell string CS changes, the number of word lines WL may also change. For example, the number of string selection transistors provided in each cell string CS may increase. As the number of string selection transistors provided in each cell string CS changes, the number of string selection lines or common source lines may also change. When the number of string selection transistors SST increases, the string selection transistors SST may be stacked in the same form as the memory cells MC.

For example, writing and reading may be performed in units of rows of cell strings CS. The cell strings CS may be selected in units of one row by the common source line CSL, and the cell strings CS may be selected in units of one row by the string selection line SSL. Also, voltage may be applied to a unit of at least two common source lines CSL. Alternatively, voltage may be applied to all of the common source lines CSL as one unit.

In a selected row of the cell strings CS, writing and reading may be performed in units of pages. A page may be one row of memory cells MC connected to one word line WL. In a selected row of the cell strings CS, memory cells MC may be selected in units of pages by word lines WL. For example, each gate electrode 131 of FIG. 1 may be connected to one of the word line WL and the string selection line SSL.

The memory cell MC may have a circuit structure in which a transistor including the gate electrode 131, the separation layer 132, and the channel layer 121 and the charge storage layer 123 are connected to each other.

The memory cells MC may be consecutively arranged in a vertical direction (e.g., Z direction) to form the cell strings CS. In addition, as shown in FIG. 4, the common source line CSL and the bit line BL may be respectively connected to both ends of the cell string CS. By applying voltage to the common source line CSL and the bit line BL, programming, reading, and erasing processes of the plurality of memory cells MC may be performed.

For example, when a memory cell MC to be written is selected, a gate voltage value of the memory cell MC may be adjusted such that no channel is formed in the selected memory cell (that is, the channel is turned off), and gate voltage values of unselected memory cells MC may be adjusted such that channels of the unselected memory cells are turned on. Accordingly, charges caused by the voltage applied to the common source line CSL and the bit line BL may tunnel through the charge tunneling layer 122 and may be stored in the charge storage layer 123 of the selected memory cell MC. Thus, desired information containing 1 or 0 may be recorded on the selected memory cell MC.

Similarly, in a read operation, reading of the selected cell may be performed. That is, after the gate voltage applied to each gate electrode 131 is adjusted such that the channel of the selected memory cell MC is turned off and the channels of the unselected memory cells MC are turned on, the state (1 or 0) of the memory cell MC may be identified by measuring current flowing in the memory cell MC by an applied voltage (Vread) between the common source line CSL and the bit line BL.

One key reliability factor required for the vertical nonvolatile memory device is data retention (that is, the ability to store charges in the charge storage layer for a long time). The vertical nonvolatile memory device may have a structure in which the memory cells MC are connected in the vertical direction. When information is stored, charges may be vertically diffused and migrate to adjacent memory cells MC, thereby affecting the operation of the adjacent memory cells MC. In the vertical nonvolatile memory device having a structure in which the plurality of memory cells MC in one cell string CS share the charge storage layer (that is, a structure in which the charge storage layer extends the same length as the channel layer), when a distance between the plurality of memory cells MC is reduced to increase memory density, charge migration may occur between the plurality of memory cells MC, and accordingly, charge retention characteristics may deteriorate.

In a direction perpendicular to the charge storage layer (e.g., in a horizontal direction), charges may migrate from the charge storage layer (e.g., 123 of FIG. 2) to the charge tunneling layer (e.g., 122 of FIG. 2) through trap-assisted tunneling or thermal emission. The degree of charge migration may be determined by a conduction band offset (CBO) at an interface between the charge storage layer and the charge tunneling layer. Charge migration may occur in a direction parallel to the charge storage layer (e.g., in a vertical direction) by lateral migration according to a gradient of charge concentration. Charge migration in the direction parallel to the charge storage layer may be governed by Poole-Frenkel tunneling. The current density due to the Poole-Frenkel tunneling may be expressed as the following Poole-Frenkel conduction equation, as in Equation (1).

$$J = q μ {N}_{c} E exp ( \frac{- q ( {E}_{T} - \sqrt{qE / π ε} )}{kT} ) \qquad ( 1 )$$

In Equation (1), J is a current density, q is an electronic charge, μ is a carrier mobility, N_{c} is a density of states in conduction band, E is an electric field, E_{T} is a trap energy, ε is permittivity, k is a Boltzmann constant, and T is a temperature.

Charge migration in the direction parallel to the charge storage layer (e.g., a vertical direction) due to the Poole-Frenkel tunneling may be determined by the trap energy E_{T} and trap density N_{T} in the charge storage layer. The trap energy may refer to a voltage barrier that electrons need to cross to move from one atom to another within a material. That is, the trap energy may refer to the depth of trap state relative to the conduction band minimum (CBM) of the material. The trap density may refer to the number of trapped charges per unit volume. This trap density may be determined using a charge pumping method. Charge retention characteristics in the direction parallel to the charge storage layer (e.g., a vertical direction) may be improved by high trap energy and high trap density.

To this end, the charge storage layer may be formed with a material having high trap energy and trap density, such as amorphous metal oxynitride in which nanocrystals having semiconductor properties are dispersed. However, this method may increase the complexity of a manufacturing process of memory devices due to the diversification of materials used in the manufacturing process.

According to one or more embodiments, the vertical nonvolatile memory device 100 has a structure in which the plurality of memory cells MC forming one cell string CS are separated by the plurality of separation layers 132. That is, the plurality of charge storage layers 123 of the plurality of memory cells MC may be separated in the vertical direction by the plurality of separation layers 132. Accordingly, unlike a charge storage layer in which structures are shared, in the vertical nonvolatile memory device 100 according to one or more embodiments, lateral migration of charges between the plurality of charge storage layers 123 may be blocked by the plurality of separation layers 132. Therefore, high charge retention characteristics in the direction parallel to the charge storage layers 123 (e.g., a vertical direction) may be achieved. Accordingly, as a threshold voltage decreases, the operating characteristics of the vertical nonvolatile memory device 100 may be improved. Also, the plurality of charge blocking layers 124 may be separated by the plurality of separation layers 132 such that the lateral migration of charges may be further reduced.

In the vertical nonvolatile memory device 100 according to one or more embodiments, the charge storage layer 123 may include a semiconductor material, such as Si. Si may form SiO₂ through an oxidation process. The charge storage layer 123 is between the charge tunneling layer 122 and the charge blocking layer 124. The charge tunneling layer 122 and the charge blocking layer 124 may include SiO₂. In this case, the charge tunneling layer 122 and the charge blocking layer 124 may be formed by oxidizing both portions of the charge storage layer 123 in the horizontal direction, and the charge storage layer 123 may include Si. Accordingly, a manufacturing process of the vertical nonvolatile memory device 100 may be simplified, and the charge tunneling layer 122 and the charge blocking layer 124 including high-quality SiO₂ may be formed.

In a process of forming the gate electrode 131, a volume reduction may occur during a process of depositing a gate material (for example, a metal). Thus, the memory cell MC may be in a state in which tensile stress is applied as a whole. In the case of memory devices using SiN as a charge storage layer, when changing SiN into SiO₂ to form a charge blocking layer, a volume increase rate may be about 1.54. In this regard, in the case of the vertical nonvolatile memory device according to one or more embodiment, in which Si is used as the charge storage layer 123, when changing Si into SiO₂ to form the charge blocking layer 124, a volume increase rate may be about 1.88 times, which is higher than a volume change rate when changing SiN into SiO₂. For example, a volume reduction amount due to deposition of the gate electrode 131 per unit memory cell MC may be about 3100 nm, and when changing Si into SiO₂ in the unit memory cell MC, a volume increase amount may be about 3200 nm. Accordingly, this may offset the volume reduction amount due to deposition of the gate electrode 131, and the compressive stress of the formed charge blocking layers 124 about about −50 MPa to about −300 MPa. Therefore, the memory cell MC may be in a state in which compressive stress is applied as a whole.

The charge storage layer 123 may include a semiconductor material, such as Si, doped with a dopant at a doping concentration of 10¹⁸ atm/cm³ or higher, for example, 10¹⁹ atm/cm³ or higher. When an n-type dopant such as As or P is applied, a work function of the charge storage layer 123 may change, and a collector-base breakdown voltage (V_{CBO}) may include. Accordingly, charge leakage from the charge storage layer 123 due to tunneling may be reduced such that the charge retention characteristics of the charge storage layer 123 may be improved. In addition, B, C, or Ge may be used as a dopant.

The plurality of memory cells MC included in one cell string CS may share the channel layer 121 and the charge tunneling layer 122, but the disclosure is not limited thereto.

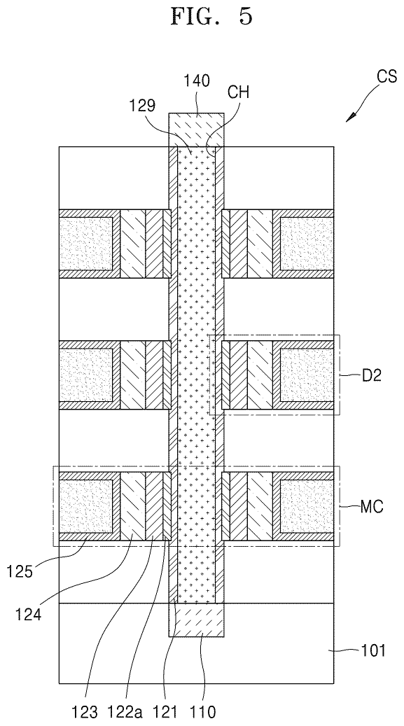

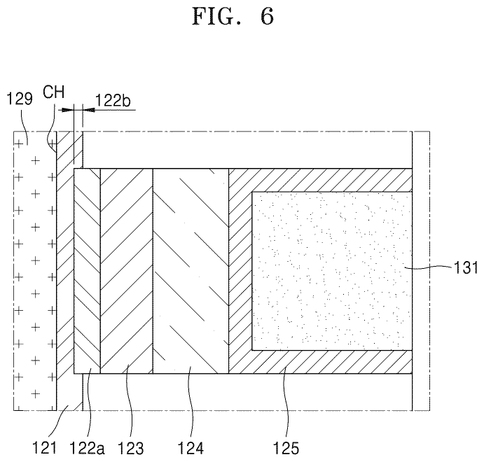

FIG. 5 is a cross-sectional view of a vertical nonvolatile memory device according to one or more embodiments. FIG. 6 is an enlarged view of area D2 of FIG. 5 according to one or more embodiments. The vertical nonvolatile memory device of FIGS. 5 and 6 differ from the vertical nonvolatile memory devices shown in FIGS. 2 and 3 in that the plurality of memory cells MC included in one cell string CS share the channel layer 121 and a plurality of charge tunneling layers 122a respectively corresponding to the plurality of memory cells MC are provided. Hereinafter, elements that perform the same function as described above may be denoted by the same reference numerals and redundant descriptions may be omitted.

Referring to FIGS. 5 and 6, shown are the plurality of charge tunneling layers 122a separated by the plurality of separation layers 132 to respectively correspond to the plurality of charge storage layers 123. For example, the charge tunneling layer 122 that is shown to be continuous in the Z-direction in FIGS. 2 and 3 may be formed to be segmented into a plurality of charge tunneling layer segments, such as the plurality of charge tunneling layers 122a. The plurality of charge tunneling layers 122a may protrude from the outer peripheral surface of the channel layer 121 and include a portion that extends into the channel layer 121. That is, the plurality of charge tunneling layers 122a may be partially inserted into the channel layer 121. An insertion distance 122b may be, for example, 5 nm. That is, in a cross-sectional view, the charge tunneling layers 122a may extend into the channel layer by about 5 nm.

As described above, charge migration between the memory cells MC may include migration in the vertical direction and migration in the horizontal direction. According to one or more embodiments, the plurality of charge tunneling layers 122a may be separated by the plurality of separation layers 132, and thus, charge migration in the vertical direction through the plurality of charge tunneling layers 122a may be blocked. Also, no charge tunneling layer 122a and charge storage layer 123 are present in an area without the gate electrode 131. Accordingly, the capacitance increases, and performance deterioration of the vertical nonvolatile memory device due to operational interference between the memory cells MC during operation of the vertical nonvolatile memory device may be alleviated. Also, according to the structure in which the charge tunneling layers 122a are partially inserted into the channel layer 121, charge loss in the vertical direction through the charge tunneling layers 122a may be reduced.

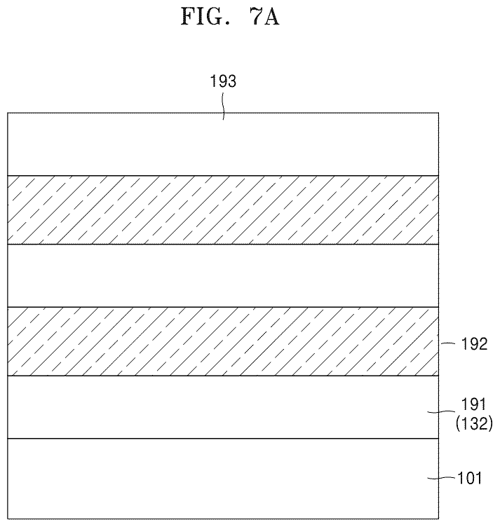

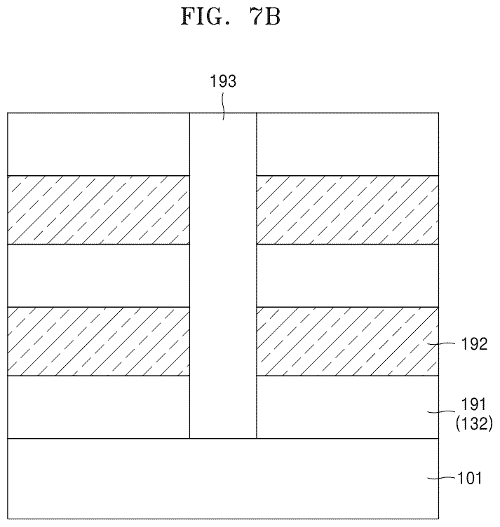

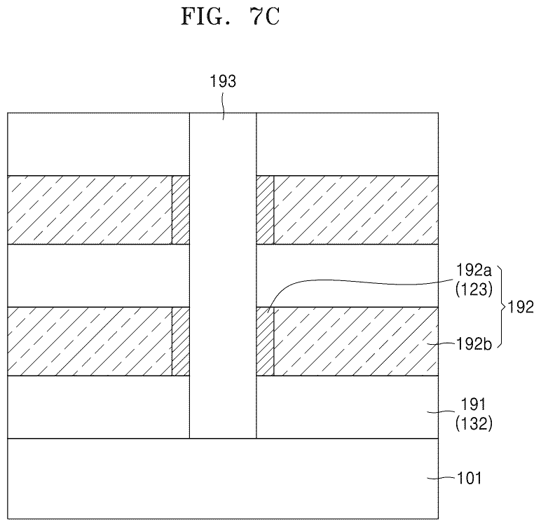

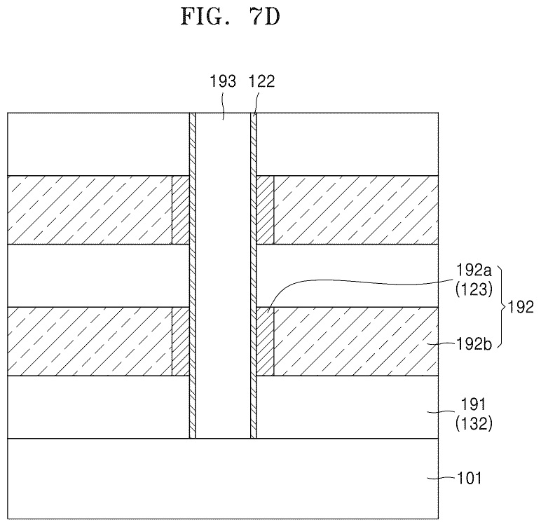

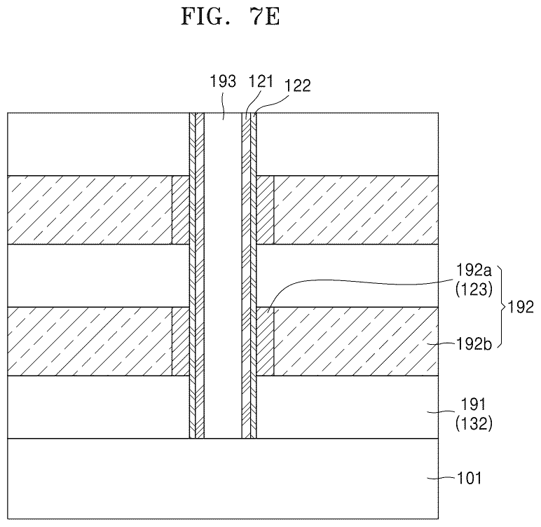

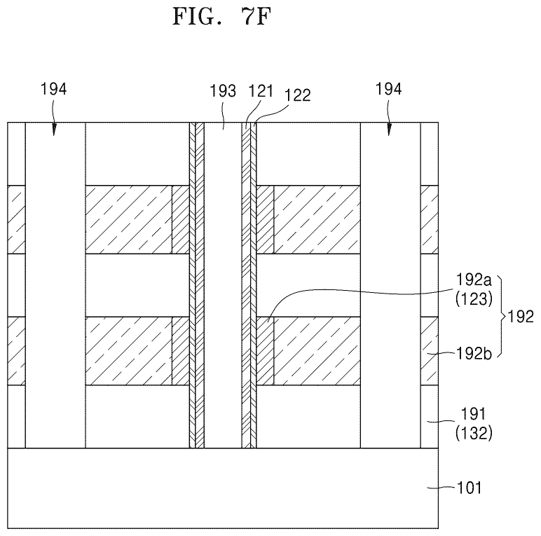

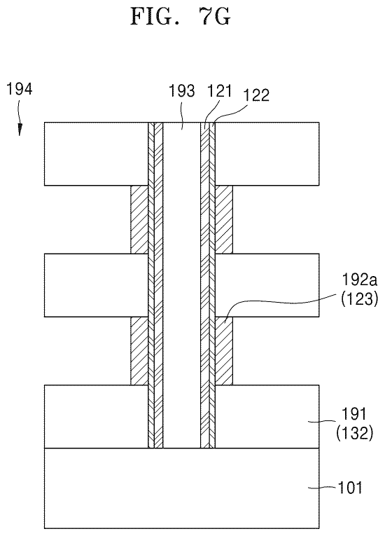

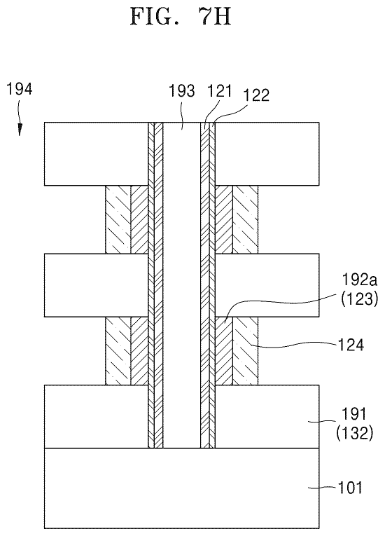

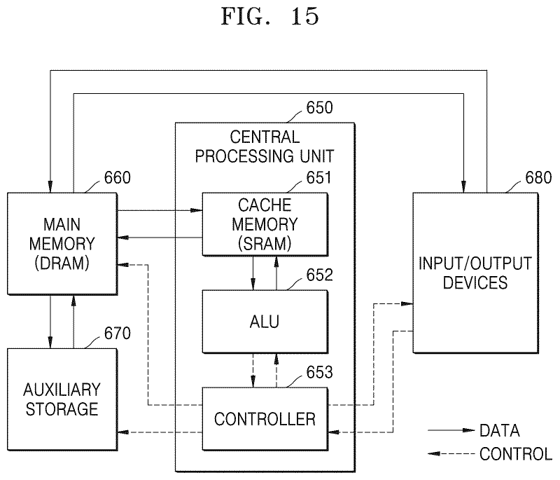

Hereinafter, embodiments of a method of manufacturing a vertical nonvolatile memory device are described. FIGS. 7A to 71 are diagrams of a method of manufacturing a vertical nonvolatile memory device according to one or more embodiments. For example, FIGS. 7A to 71 are diagrams of a method of manufacturing the vertical nonvolatile memory device shown in FIGS. 2 and 3.

First, referring to FIG. 7A, a plurality of separation layers 191 and a plurality of semiconductor material layers 192 may be alternately stacked on the substrate 101. The substrate 101 may include a single crystal silicon substrate, a compound semiconductor substrate, or an SOI substrate. The separation layer 132 of FIG. 1 may be formed by a separation layer 191. A semiconductor material layer 192 may include Si, such as polysilicon.

As shown in FIG. 7B, a through hole 193 that passes through the plurality of separation layers 191 and the plurality of semiconductor material layers 192 may be formed. The through hole 193 may extend to the upper surface of the substrate 101. The through hole 193 may be, for example, cylindrical, but is not limited thereto. The through hole 193 may be formed by using an etching process.

As shown in FIG. 7C, a dopant may be injected into the plurality of semiconductor material layers 192 through the through hole 193. As a dopant, for example, B, C, Ge, As, or P may be used. A first area 192a adjacent to the through hole 193 of the semiconductor material layer 192 may be doped at a high concentration. A second area 192b, which is an area adjacent the first area 192a such that the first area 192a is between the second area 192b and the through hole 193, is not doped. In this case, the undoped second area 192b may refer to not only to an area with no dopant at all, but also to an area doped to a degree that does not show a significant difference in etch rate from the etch rate of the first area 192a in an etching process to be described below. For example, a doping process may be performed such that a doping concentration of the first area 192a is 10¹⁸ atm/cm³ or higher (for example, 10¹⁹ atm/cm³ or higher).

Referring to FIG. 7D, the charge tunneling layer 122 may be formed inside the through hole 193. For example, the charge tunneling layer 122 may be formed on an inner wall of the through hole 193, which has, for example, a cylindrical shape. The charge tunneling layer 122 may include, for example, SiO₂ or metal oxide. In one or more embodiments, the charge tunneling layer 122 may include SiO₂. The charge tunneling layer 122 may be entirely formed on (e.g., conformally covers) the inner wall of the through hole 193. Accordingly, the charge tunneling layer 122 having the structure shown in FIG. 2, in which the plurality of memory cells MC share the charge tunneling layer 122, may be formed. A method of forming the charge tunneling layer 122 is not particularly limited. For example, the charge tunneling layer 122 may be formed by using chemical vapor deposition, atomic layer deposition, or the like.

As shown in FIG. 7E, the channel layer 121 may be formed inside the charge tunneling layer 122. The channel layer 121 may include Si, Ge, SiGe, and a group III-V semiconductor, as described above, an oxide semiconductor, a nitride semiconductor, a nitrous oxide semiconductor, a 2D semiconductor material, quantum dots, or an organic semiconductor. For example, the channel layer 121 may include Si and may be doped with impurities. The method of forming the channel layer 121 is not particularly limited. For example, the channel layer 121 may be formed by using atomic deposition or the like.

In FIG. 7F, a partition groove 194 that partitions the plurality of cell strings CS may be formed. The partition groove 194 may be referred to as a word line cut. The partition groove 194 may be formed by penetrating from the upper surface of a stack in which the plurality of separation layers 191 and the plurality of semiconductor material layers 192 are stacked to the upper surface of the substrate 101. The partition groove 194 may be formed, for example, to surround a portion where the cell string CS is to be formed. In a plan view, the partition groove 194 may be formed in a grid shape that separates the plurality of cell strings CS. The partition groove 194 may be formed by using an etching process. The second area 192b of the semiconductor material layer 192 may be exposed through the partition groove 194.

Next, a process of forming the charge storage layer 123 may be performed. Referring to FIG. 7G, the second area 192b of the semiconductor material layer 192, which is exposed through the partition groove 194, may be removed by using, for example, a gas etching process or a wet etching process. The first area 192a remains, and accordingly, the charge storage layer 123 may be formed. Selective etching of the second area 192b may be performed due to a difference in etch rate according to a difference in doping concentration between the first area 192a and the second area 192b.

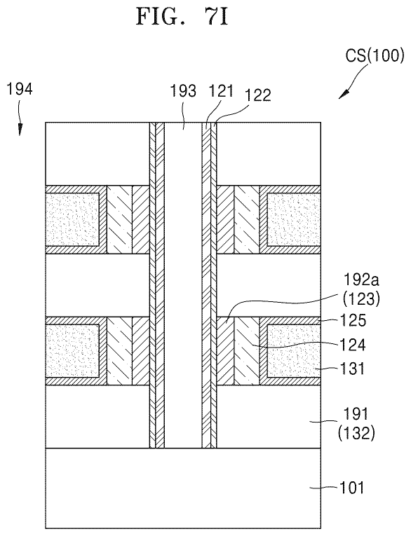

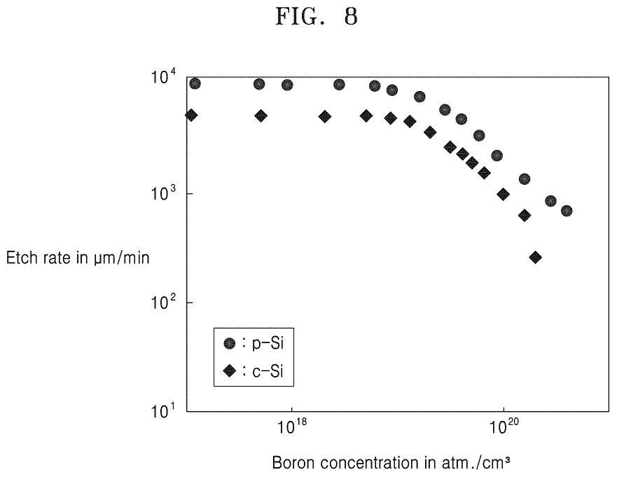

FIG. 8 is a graph illustrating a change in silicon etch rate according to the concentration of a dopant in an etching process using tetramethylammonium hydroxide (TMAH), according to one or more embodiments. In FIG. 8, the concentration of TMAH is 20% and the process temperature is 80° C. The dopant is B.

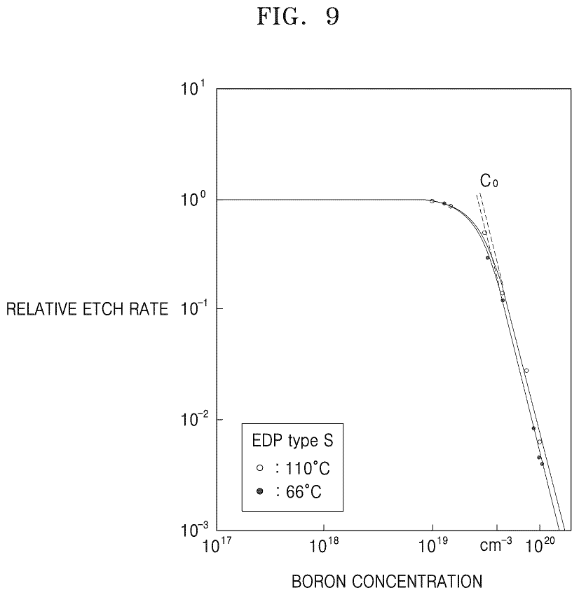

FIG. 9 is a graph illustrating a change in silicon etch rate according to the concentration of a dopant in an etching process using an ethylenediamine-pyrocatechol-water solution (EDP) aqueous solution according to one or more embodiments. In FIG. 9, the process temperature is 49° C., and 66° C. and 110° C. respectively represent temperatures of the EDP aqueous solution.

Referring to FIGS. 8 and 9, when the concentration of the dopant exceeds 10¹⁸ atm/cm³, for example, 10¹⁹ atm/cm³, the silicon etch rate rapidly decreases. Accordingly, the undoped second area 192b may be removed by using a wet etching process or a gas etching process, and the first area 192a doped at a high concentration may not be removed but remain.

The charge blocking layer 124 may be formed. As shown in FIG. 7H, the charge blocking layer 124 may be formed by depositing, for example, SiO₂, metal oxide, or metal nitride adjacent to the first area 192a through the partition groove 194. For example, the charge blocking layer 124 may include SiO₂. In this case, the charge blocking layer 124 may be formed by partially oxidizing Si in the first area 192a. That is, the charge blocking layer 124 may be formed by partially oxidizing an outer area of the first area 192a (that is, an area opposite the through hole 193). Accordingly, the process may be simplified.

The gate electrode 131 may be formed. As shown in FIG. 7I, the gate electrode 131 may be formed by depositing, for example, a metal material, conductive oxide, metal nitride, Si doped with impurities, or a 2D conductive material adjacent to the charge blocking layers 124 through the partition groove 194. Before the gate electrode 131 is formed, the diffusion prevention layer 125 may be formed first. For example, the diffusion prevention layer 125 may be formed by depositing at least one of Ti, Zr, V, Al, La, Nb, and Ta, or nitride including at least one of the aforementioned materials adjacent to the charge blocking layer 124 and the upper and lower surfaces of the separation layer 132. Then, the gate electrode 131 may be formed to contact the diffusion prevention layer 125.

As described above, in the process of forming the charge blocking layer 124 by partially changing Si in the first area 192a into SiO₂, the volume increase amount may be about 3200 nm. In the process of forming the gate electrode 131, the volume reduction amount may be about 3100 nm. Accordingly, the volume reduction amount in the process of forming the gate electrode 131 may be offset by the volume increase amount in the process of forming SiO₂. Because the volume increase amount in the process of forming SiO₂ is slightly greater than the volume reduction amount in the process of forming the gate electrode 131, as a result, compressive stress of about −30 MPa to about −300 MPa may be applied to the charge blocking layer 124.

Accordingly, the vertical nonvolatile memory device 100 shown in FIGS. 2 and 3 may be manufactured.

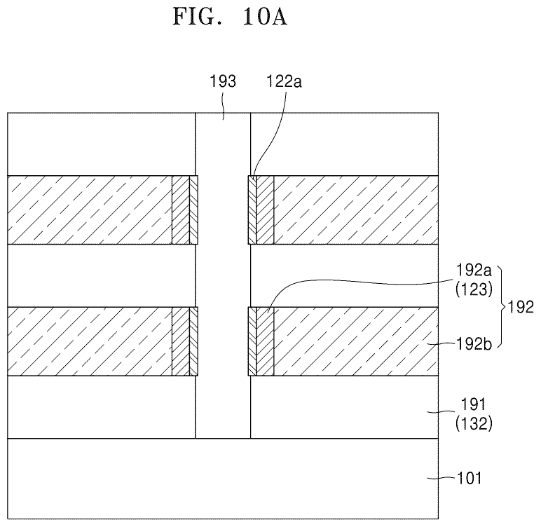

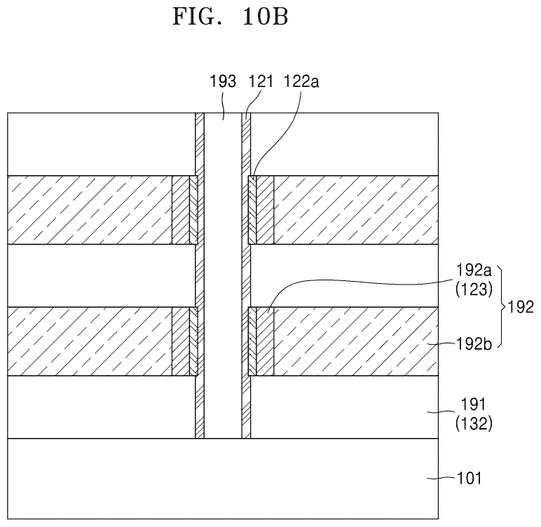

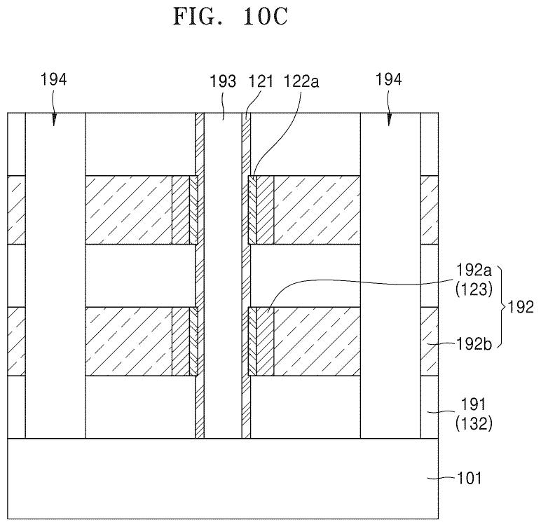

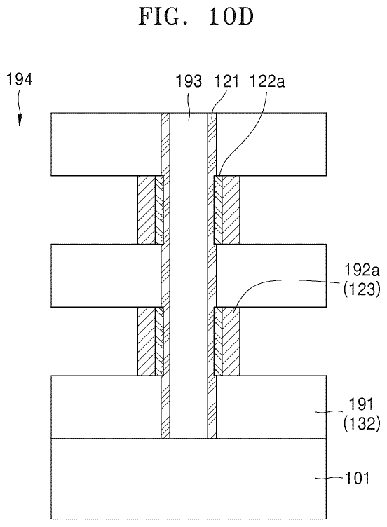

FIGS. 10A to 10F are diagrams of a method of manufacturing a vertical nonvolatile memory device according to one or more embodiments. For example, FIGS. 10A to 10F are diagrams of a method of manufacturing the vertical nonvolatile memory device shown in FIGS. 5 and 6. Referring to FIGS. 7A to 7C and FIGS. 10A to 10F, an example of the method of manufacturing the vertical nonvolatile memory device is described.

By the aforementioned process of FIGS. 7A to 7C, the plurality of separation layers 191 and the plurality of semiconductor material layers 192 may be alternately stacked on the substrate 101, the through hole 193 that passes through the plurality of separation layers 191 and the plurality of semiconductor material layers 192 may be formed, and a dopant may be injected into the plurality of semiconductor material layers 192 through the through hole 193 such that the first area 192a, which is adjacent to the through hole 193 and doped at a high concentration, may be formed in the plurality of semiconductor material layers 192 and the undoped second area 192b may be formed adjacent to the first area 192a. For example, the doping concentration of the first area 192a may be 10¹⁸ atm/cm³ or higher, for example, 10¹⁹ atm/cm³ or higher.

Referring to FIG. 10A, the plurality of charge tunneling layers 122a may be formed at positions corresponding to first areas 192a of the plurality of semiconductor material layers 192, respectively. For example, the charge tunneling layer 122a may be formed by partially oxidizing Si in the first area 192a to form SiO₂. That is, the charge tunneling layer 122 may be formed by partially oxidizing an inner area of the first area 192a (that is, an area close to the through hole 193). In this process, the volume of SiO₂ may increase compared to the volume of Si, and the charge tunneling layer 122a may protrude into the through hole 193. Accordingly, a structure in which the plurality of charge tunneling layers 122a of the plurality of memory cells MC shown in FIG. 4 are separated by the separation layers 132 may be formed.

As shown in FIG. 10B, the channel layer 121 may be formed inside the charge tunneling layer 122a. The channel layer 121 may include Si, Ge, SiGe, and a group III-V semiconductor, as described above, an oxide semiconductor, a nitride semiconductor, a nitrous oxide semiconductor, a 2D semiconductor material, quantum dots, or an organic semiconductor. For example, the channel layer 121 may include Si and may be doped with impurities. The method of forming the channel layer 121 is not particularly limited. For example, the channel layer 121 may be formed by using atomic deposition or the like. Because the charge tunneling layer 122a protrudes into the through hole 193, the charge tunneling layer 122a has a structure in which the charge tunneling layer 122a is inserted into the channel layer 121.

A partition groove 194 that partitions the plurality of cell strings CS may be formed. Referring to FIG. 10C, the partition groove 194 may be formed by penetrating from the upper surface of a stack in which the plurality of separation layers 191 and the plurality of semiconductor material layers 192 are stacked to the upper surface of the substrate 101. The partition groove 194 may be formed, for example, to surround a portion where the cell string CS is to be formed. In a plan view, the partition groove 194 may be formed in a grid shape that separates the plurality of cell strings CS. The partition groove 194 may be formed by using an etching process. The second area 192b of the semiconductor material layer 192 may be exposed through the partition groove 194.

Next, the process of forming the charge storage layer 123 may be performed. Referring to FIG. 10D, the second area 192b of the semiconductor material layer 192, which is exposed through the partition groove 194, may be removed by using, for example, a gas etching process or a wet etching process. Thus, the first area 192a remains, and accordingly, the charge storage layer 123 may be formed. As described above, selective etching of the second area 192b may be performed due to a difference in etch rate according to a difference in doping concentration between the first area 192a and the second area 192b.

The charge blocking layer 124 may be formed. As shown in FIG. 10E, the charge blocking layer 124 may be formed by depositing, for example, SiO₂, metal oxide, or metal nitride adjacent to the first area 192a through the partition groove 194. For example, the charge blocking layer 124 may include SiO₂. In this case, the charge blocking layer 124 may be formed by partially oxidizing Si in the first area 192a. Accordingly, the process may be simplified.

The gate electrode 131 may be formed. As shown in FIG. 10F, the gate electrode 131 may be formed by depositing, for example, a metal material, conductive oxide, metal nitride, Si doped with impurities, or a 2D conductive material adjacent to the charge blocking layers 124 through the partition groove 194. Before the gate electrode 131 is formed, the diffusion prevention layer 125 may be formed first. For example, the diffusion prevention layer 125 may be formed by depositing at least one of Ti, Zr, V, Al, La, Nb, and Ta, or nitride including at least one of the aforementioned materials on the outside of the charge blocking layer 124 and the upper and lower surfaces of the separation layer 132. Then, the gate electrode 131 may be formed to contact the diffusion prevention layer 125.

As described above, in the process of forming the charge blocking layer 124 by changing Si into SiO₂, the volume increase amount may be about 3200 nm. In the process of forming the gate electrode 131, the volume reduction amount may be about 3100 nm. Therefore, the volume increase amount may offset the volume reduction amount, and thus, overall, the compressive stress of the charge blocking layers 124 may be about −30 MPa to about −300 MPa.

Accordingly, the vertical nonvolatile memory device 100 shown in FIGS. 5 and 6 may be manufactured.

The vertical nonvolatile memory device according to one or more embodiments may be applied to various electronic apparatuses.

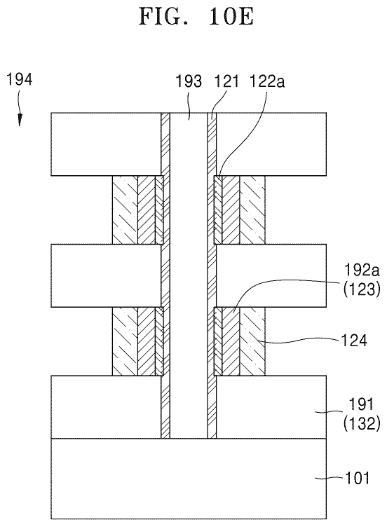

FIG. 11 is a block diagram of a display driver integrated circuit (DDI) 200 and a display apparatus 220 including the DDI 200, according to one or more embodiments. Referring to FIG. 11, the DDI 200 may include a controller 202, a power supply circuit 204, a driver 206, and a memory 208. The controller 202 may receive and decode commands applied from a main processing unit (MPU) 222 and control respective blocks of the DDI 200 to implement operations according to the commands. The power supply circuit 204 may generate a driving voltage in response to the control by the controller 202. In response to the control by the controller 202, the driver 206 may drive a display panel 224 by using the driving voltage generated by the power supply circuit 204. The display panel 224 may include, for example, a liquid crystal display panel, an organic light-emitting device (OLED) display panel, or a plasma display panel. The memory 208 may temporarily store commands input to the controller 202, may control signals output from the controller 202, and/or store necessary data, and may include a memory such as random access memory (RAM) or read-only memory (ROM). For example, the memory 208 may include the vertical nonvolatile memory device 100 according to one or more embodiments.

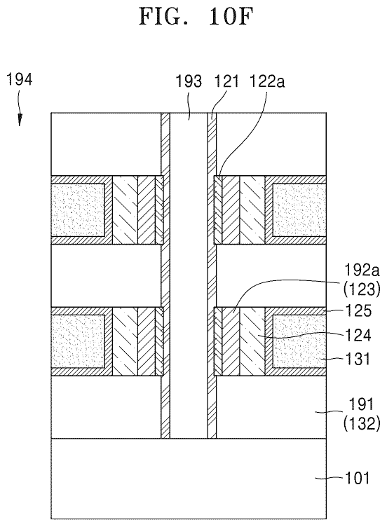

FIG. 12 is a diagram of an electronic apparatus 300 according to one or more embodiments. Referring to FIG. 12, the electronic apparatus 300 includes a memory 310 and a memory controller 320. The memory controller 320 may control the memory 310 to read data from the memory 310 and/or write data into the memory 310 in response to a request from a host 330. The memory 310 may include the vertical nonvolatile memory device 100 according to one or more embodiments.

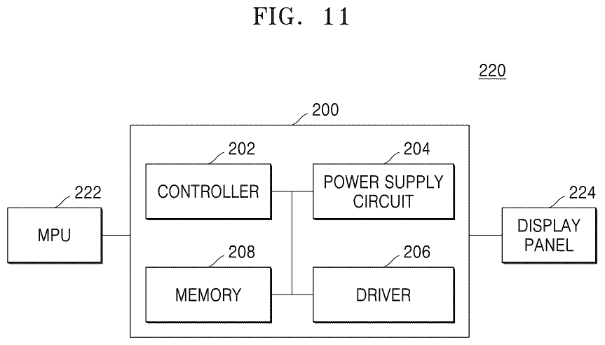

FIG. 13 is a diagram of an electronic apparatus 400 according to one or more embodiments. Referring to FIG. 13, the electronic apparatus 400 may configure a wireless communication apparatus or an apparatus that may transmit and/or receive information in a wireless environment. The electronic apparatus 400 may include a controller 410, an input/output (I/O) 420, a memory 430, and a wireless interface 440, and these elements may be interconnected with each other through a bus 450.

The controller 410 may include at least one of a microprocessor, a digital signal processor, or a similar processing apparatus. The I/O 420 may include at least one of a keypad, a keyboard, or a display. The memory 430 may be used to store commands executed by the controller 410. For example, the memory 430 may be used to store user data. The electronic apparatus 400 may use the wireless interface 440 to transmit/receive data through a wireless communication network. The wireless interface 440 may include an antenna and/or a wireless transceiver. In one or more embodiments, the electronic apparatus 400 may be used for a third generation communication system, for example, a communication interface protocol of a third generation communication system, such as code division multiple access (CDMA), global system for mobile communications (GSM), north American digital cellular (NADC), extended-time division multiple access (E-TDMA), and/or wideband code division multiple access (WCDMA). The memory 430 of the electronic apparatus 400 may include the vertical nonvolatile memory device 100 according to one or more embodiments.

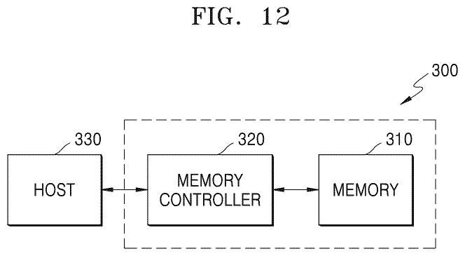

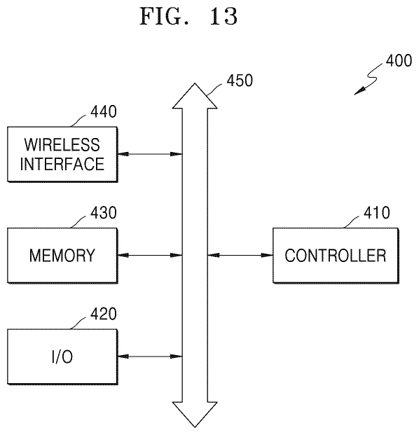

FIG. 14 is a diagram of a device architecture that may be applied to an electronic apparatus, according to one or more embodiments.

Referring to FIG. 14, an electronic device architecture 500 may include a memory 510 and a controller 530, and may further include an arithmetic logic unit (ALU) 520. The memory 510, the ALU 520, and the controller 530 may be electrically connected to each other. For example, the electronic device architecture 500 may be implemented as one chip including the memory 510, the ALU 520, and the controller 530. The memory 510, the ALU 520, and the controller 530 may be interconnected to each other through a metal line on-chip and may directly communicate with each other. The memory 510, the ALU 520, and the controller 530 may be monolithically integrated on one substrate 101 (see FIG. 1) to form one chip. Input/output devices 550 may be connected to the electronic device architecture (chip) 500. Also, the memory 510 may include both a main memory and a cache memory. The electronic device architecture (chip) 500 may include an on-chip memory processing unit. The memory 510, the ALU 520, and/or the controller 530 may each independently include the vertical nonvolatile memory device 100 according to one or more embodiments.

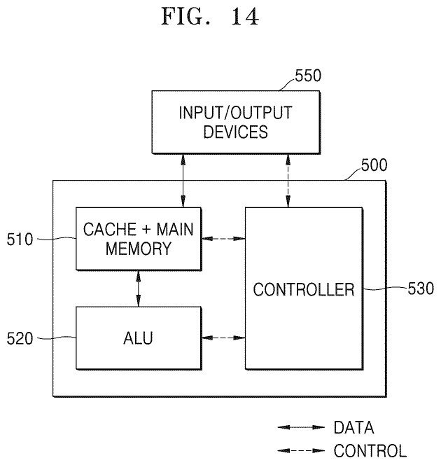

FIG. 15 is a diagram of a device architecture that may be applied to an electronic apparatus, according to one or more embodiments.

Referring to FIG. 15, a cache memory 651, an ALU 652, and a controller 653 may constitute a central processing unit (CPU) 650, and the cache memory 651 may include static RAM (SRAM). Separately from the CPU 650, a main memory 660 and an auxiliary storage 670 may also be provided. In addition, input/output devices 680 may be provided. The main memory 660 may include, for example, dynamic RAM (DRAM) and may include the vertical nonvolatile memory device 100 according to one or more embodiments.

In some cases, an electronic device architecture may be implemented in a form where computing devices and memory devices are adjacent to each other on one chip, without isolation of sub-units.

The vertical nonvolatile memory device according to one or more embodiments may be applied to various user apparatuses, such as a computer, a mobile computer, an ultra-mobile personal computer (UMPC), a workstation, a netbook, a PDA, a portable computer, a web tablet, a wireless phone, a mobile phone, a smartphone, a digital camera, a digital audio recorder, a digital audio player, a digital picture recorder, a digital picture player, a digital video recorder, a digital video player, an apparatus capable of transmitting and receiving information in a wireless environment, and a home network.

The disclosure has been described with reference to the embodiments shown in the drawings, but these are merely examples, and it should be understood that various modifications and other equivalent embodiments may be made by those of ordinary skill in the art. Although many details are described in the above description, they should be construed as examples of specific embodiments rather than limiting the scope of the disclosure. Therefore, the scope of the disclosure should not be determined by the described embodiments, but rather by the technical idea stated in the claims.

According to the vertical nonvolatile memory device according to one or more embodiments, because horizontal migration of charges between the plurality of charge storage layers is blocked by the plurality of separation layers, high charge retention characteristics may be achieved, and operating characteristics of the vertical nonvolatile memory device may be improved.

According to the method of manufacturing the vertical nonvolatile memory device according to one or more embodiments, because the charge storage layer may be formed by using selective etching using a difference in etch rate according to the doping concentration of the semiconductor material layer, the manufacturing process may be simplified.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A nonvolatile memory device comprising:
a plurality of cell strings,
wherein each cell string of the plurality of cell strings comprises:
a channel layer extending in a first direction;
at least one charge tunneling layer adjacent to the channel layer in a second direction intersecting the first direction;
a plurality of charge storage layers adjacent to the at least one charge tunneling layer in the second direction, the plurality of charge storage layers spaced apart in the first direction;
a plurality of charge blocking layers adjacent to respective charge storage layers of the plurality of charge storage layers in the second direction;
a plurality of gate electrodes adjacent to respective charge blocking layers of the plurality of charge blocking layers in the second direction; and
a plurality of separation layers configured to isolate the plurality of charge storage layers, the plurality of charge blocking layers, and the plurality of gate electrodes in the first direction, and
wherein the plurality of charge storage layers comprise a semiconductor material doped with a dopant at a doping concentration of 10¹⁸ atm/cm³ or higher.

2. The nonvolatile memory device of claim 1, wherein the semiconductor material comprises silicon (Si).

3. The nonvolatile memory device of claim 2, wherein the semiconductor material comprises polysilicon.

4. The nonvolatile memory device of claim 1, wherein the dopant comprises an n-type dopant.

5. The nonvolatile memory device of claim 4, wherein the n-type dopant comprises arsenic (As) or phosphorus (P).

6. The nonvolatile memory device of claim 1, wherein the dopant comprises boron (B), carbon (C), or germanium (Ge).

7. The nonvolatile memory device of claim 1, wherein the at least one charge tunneling layer extends in the first direction and is configured to be shared by the plurality of charge storage layers.

8. The nonvolatile memory device of claim 1, wherein the at least one charge tunneling layer comprises a plurality of charge tunneling layer that are respectively separated by the plurality of separation layers and respectively correspond to the plurality of charge storage layers.

9. The nonvolatile memory device of claim 8, wherein the plurality of charge tunneling layers protrude from an outer peripheral surface of the channel layer to an inner side of the channel layer.

10. The nonvolatile memory device of claim 1, wherein the at least one charge tunneling layer comprises silicon oxide.

11. The nonvolatile memory device of claim 1, wherein a compressive stress of the plurality of charge blocking layers is −50 MPa to −300 MPa.

12. A method of manufacturing a memory device, the method comprising:
alternately stacking a plurality of separation layers and a plurality of semiconductor material layers on a substrate;
forming a through hole in the plurality of separation layers and the plurality of semiconductor material layers;
forming, in each semiconductor material layer of the plurality of semiconductor material layers, a first area adjacent to the through hole and a second area adjacent to the first area, by injecting a dopant into the plurality of semiconductor material layers by the through hole, wherein the first area is doped with the dopant, and the second area is not doped;
forming at least one charge tunneling layer on an inner wall of the through hole;
forming a channel layer on an inner wall of the at least one charge tunneling layer;
forming a partition groove partitioning a plurality of cell strings; and
forming a charge storage layer by etching and removing the second area of each semiconductor material layer of the plurality of semiconductor material layers through the partition groove, such that the first area of each semiconductor material layer of the plurality of semiconductor material layers remains.

13. The method of claim 12, wherein the plurality of charge storage layers comprise a semiconductor material, and
wherein the semiconductor material comprises silicon (Si).

14. The method of claim 12, wherein a doping concentration of the first area is 10¹⁸ atm/cm³ or higher.

15. The method of claim 12, wherein the at least one charge tunneling layer comprises silicon oxide and conformally covers the inner wall of the through hole.

16. The method of claim 12, wherein the forming of the at least one charge tunneling layer comprises forming a plurality of charge tunneling layers at positions respectively corresponding to the first area of each semiconductor material layer of the plurality of semiconductor material layers.

17. The method of claim 16, wherein the forming of the plurality of charge tunneling layers comprises forming silicon oxide by partially oxidizing silicon in the first area, and
wherein the silicon oxide protrudes inward from the inner wall of the through hole.

18. The method of claim 12, further comprising:
forming a charge blocking layer through the partition groove; and
forming a gate electrode adjacent to the charge blocking layer.

19. The method of claim 18, wherein the semiconductor material layer comprises silicon, and
wherein the forming the charge blocking layer comprises forming silicon oxide by partially oxidizing silicon in each first area of each semiconductor material layer of the plurality of semiconductor material layers.

20. An electronic apparatus comprising:
a memory; and
a memory controller configured to control the memory to read data from the memory and/or write data into the memory,
wherein the memory comprises a nonvolatile memory device,
wherein the nonvolatile memory device comprises a plurality of cell strings, and
wherein each cell string of the plurality of cell strings comprises:
a channel layer extending in a first direction;
at least one charge tunneling layer adjacent to the channel layer in a second direction intersecting the first direction;
a plurality of charge storage layers adjacent to the at least one charge tunneling layer in the second direction, the plurality of charge storage layers spaced apart in the first direction;
a plurality of charge blocking layers adjacent to respective charge storage layers of the plurality of charge storage layers in the second direction;
a plurality of gate electrodes adjacent to respective charge blocking layers of the plurality of charge blocking layers in the second direction; and
a plurality of separation layers configured to isolate the plurality of charge storage layers, the plurality of charge blocking layers, and the plurality of gate electrodes in the first direction,
wherein the plurality of charge storage layers comprise a semiconductor material doped with a dopant at a doping concentration of 10¹⁸ atm/cm³ or higher.
